(19) United States
(12) Patent Application Publication
(10) Pub. No.: US 2011/0274296 A1
(43) Pub. Date: Nov. 10, 2011

(54) Ear Tip Method and Apparatus

(76) Inventor: Victor Kingsun Wai, Sui Lam NT (HK)

(21) Appl. No.: 12/774,171

(22) Filed: May 5, 2010

(51) Int. Cl. H03F 99/00; H04R 25/00

(52) U.S. Cl. 381/121; 381/380

(57) ABSTRACT

An ear tip for a sound device. The ear tip has an asymmetrical arrangement which more closely aligns with a user's ear canal. The ear tip includes an ear tip base, ear tip shaft, and a first group of low-profile flanges.

The ear tip is arranged along an ear tip central axis. The ear tip has a sound tube connection and a sound channel which extends through the ear tip base and ear tip shaft. The first group of low-profile flanges are spaced along an ear tip shaft axis, and extend radially from the ear tip shaft in perpendicular alignment to the ear tip shaft axis. A first flange, a second flange and an intermediate flange are provided. Each flange is constructed of a flat roof with a downwardly transitioning radial wall. There is a space between each of the flanges. The flanges seal against the ear wall to attenuate sound and reduce resonance.

### RELATED APPLICATIONS

This application claims priority benefit and incorporates herein by reference U.S. Ser. No. 12/415,457 filed Mar. 31, 2009 and U.S. Ser. No. 12/723,673 filed Mar. 29, 2010.

### BACKGROUND

U.S. 2006/0285715 is a US patent application for high fidelity noise excluding earphones with ergonomically designed construction. As can be seen in paragraph 30 “the ear tip may comprise a triple flange ear tip, where each of the three flanges may be generally round. Use of the three ear tip flanges may increase the percentage of persons who can obtain a good comfortable seal in the ear canal. The ear tip flanges may be in a decreasing size, whereas the smallest flange may be closest to the tip of the earphone, and the largest flange may be farthest away from the ear tip of the ear phone. Consequently, if the smallest flange does not seal the ear canal well, a slightly larger flange may do so, and if the flange also does not completely seal the ear canal, the largest flange may do so, thus ensuring a comfortable and good seal of the ear canal for a larger number of users than if one flange were used.”

U.S. 2005/0147267 is a US patent application which discloses a one size fits most hearing aid where as can be seen in the abstract “the ear tip additionally comprises three flanges decreasing in size towards the flange closest to the ear canal, and the hearing aid can be inserted into the ear canal in any orientation.” As can be seen in paragraph 49 “ear tip may have rotational symmetry around its axis and the axis of the hearing aid. In particular, ear tip flanges (first ear tip flange, second ear tip flange and third ear tip flange) and the ear tip stem may all be generally round. The use of the three ear tip flanges may increase the percentage of persons who can obtain a good comfortable seal in the ear canal. The ear tip flanges are in a decreasing size, whereas the smallest flange is closest to the tip of the hearing aid and the largest flange is farthest away from the tip of the hearing aid.”

U.S. Pat. No. 5,113,967 discloses an audibility earplug where the earplug uses damping to render unimportant a Hemholtz resonance between the acoustic mass intrinsic to a sound channel thereof and the compliance of air in the ear canal, in combination with a readily manufacturable external structure coupled to the sound channel to increase response characteristics at higher frequencies.

U.S. RE38,351 discloses a high fidelity insert earphone and method of making same, where the insert earphone is provided in which a piece of foam material is used to resiliently mount a receiver within a chamber portion of a one-piece plastic housing member. The receiver has an output port extending through a central aperture of the piece of foam material and into one end of a passage defined by a tubular portion of the housing member with a damper being disposed in the other end of the passage. The tubular portion is inserted into an ear tip . . . referring to column 3 around line 47 “the coupling device is in the form of an ear tip of a soft compliant material and has three outwardly projecting flange portions which are of generally conical form and a progressively increasing diameters, arranged to conform to the inner surface portions of the entrance of the ear canal of the user and to provide a seal limiting transmission of sound to the ear canal.”

U.S. Pat. No. 5,692,059 discloses two active element in-the-ear microphone system. As can be seen in column 5 around line 13 “a compliant silicon flanged ear canal tip . . . includes . . . a silicone multi-flanged ear canal tip.”

U.S. Pat. No. 6,411,722 discloses an earphone for an RF transmitting device, where as can be seen in column 2 around line 51 “the earphone comprises an ear tip with a cylindrical housing, the ear tip being formed with a Faraday cage for reducing or eliminating radiation emitted from the ear tip.”

U.S. Pat. No. 6,513,621 discloses a method of producing and making use of ear tips having a filled airtight chamber, where the ear tip is used in connection with a stethoscope. The ear tip is formed of a single piece of molded elastomeric material and is inverted and sealed to form a sealed chamber that is filled with a liquid gelatin, where a standard load deforms the liquid gelatin filled cavity under principles of displacement to provide the ear tips capability of contouring to the configurations of the outer ear canal.

### BRIEF DESCRIPTION OF THE DRAWINGS

FIG. 1 is an elevational view of an asymmetrical ear tip;

FIG. 2 is a cross-sectional elevational view of an asymmetrical ear tip;

FIG. 2A is a cross-sectional elevation view of an alternative embodiment of the asymmetrical ear tip;

FIG. 2B is a perspective view of an alternative embodiment of the asymmetrical ear tip;

FIG. 2C is a cross-sectional elevational view of an alternative embodiment of the asymmetrical ear tip;

FIG. 3A is a perspective schematic view of a user utilizing an ear tip;

FIG. 3B is a side perspective view of a combination sound amplifier and asymmetrical ear tip;

FIG. 4A is a detailed perspective view of an ear tip insert configuration;

FIG. 4B is a detailed perspective view of an ear tip removal configuration;

FIG. 5 is a schematic view of a sound amplifier resonance reduction system;

FIG. 6 is an exploded perspective view of a sound amplifier with ear tip kit;

FIG. 7 is a schematic flow chart of a method of utilizing an ear tip.

### DESCRIPTION OF THE PREFERRED EMBODIMENTS

What is generally provided is an asymmetrically aligned ear tip which is configured to reduce resonant feedback during utilization of a sound device and provide an ear canal alignment to provide improved fitting of the ear tip into the user's ear while providing a seating plane for the sound device to attach to the ear tip.

A user's ear canal is generally disposed at an angular direction away from the external portion of the ear such that when an ear tip is inserted into the ear canal, the central axis of the ear tip generally extends out of the ear at an odd angle. To present a generally perpendicular axis to the outer portion of the ear, an asymmetrically aligned ear tip is provided. In addition, to more easily matching the inner wall of the ear canal, a series of low profile ear tip flanges are arranged along the ear tip to provide for reduced sound penetration and reduction of sound resonance or feedback which may occur during utilization of a sound device such as a sound amplifier or hearing aid.

A discussion of the ear tip apparatus will be provided followed by a discussion of the ear tip apparatus in combination with a plurality of sound devices, followed by a detailed discussion of a sound amplifier resonance reduction system, followed by a method of utilizing an ear tip.

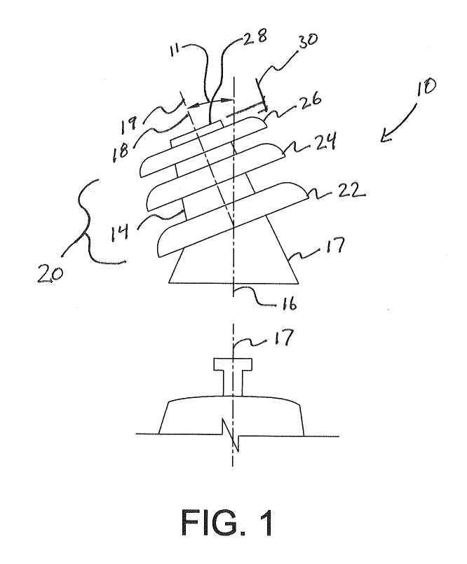

Referring to FIG. 1, an asymmetrically aligned ear tip is provided. In the current embodiment, the ear tip 10 is provided as an angularly aligned ear tip. The ear tip includes an ear tip base 12 an ear tip shaft 14 and a first group of low profile ear tip flanges 20. All of the main elements of the ear tip 10 are arranged about an ear tip axis 19. The ear tip axis, or central axis 19, is generally asymmetrical in arrangement. Thus the arrangement of the ear tip base 12, the ear tip shaft 14, and the first group of low-profile ear tip flanges 20 is also somewhat asymmetrical in arrangement.

The ear tip central axis 19 defines a length of the ear tip which ranges from approximately ½″ to approximately ⅜″. The ear tip central axis 19 may be angular in orientation, semi circular in orientation, or a combination of linear or curvilinear arrangements as depending upon the required ear tip configuration to match the user's ear canal.

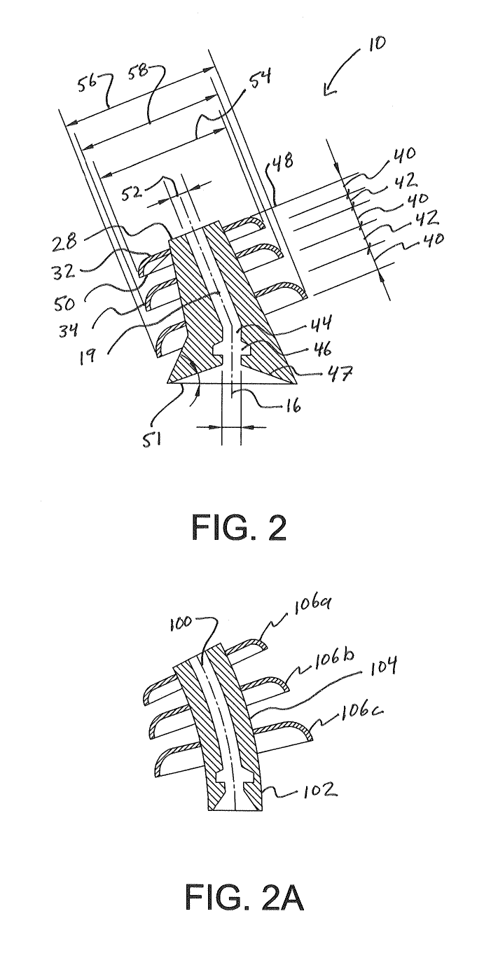

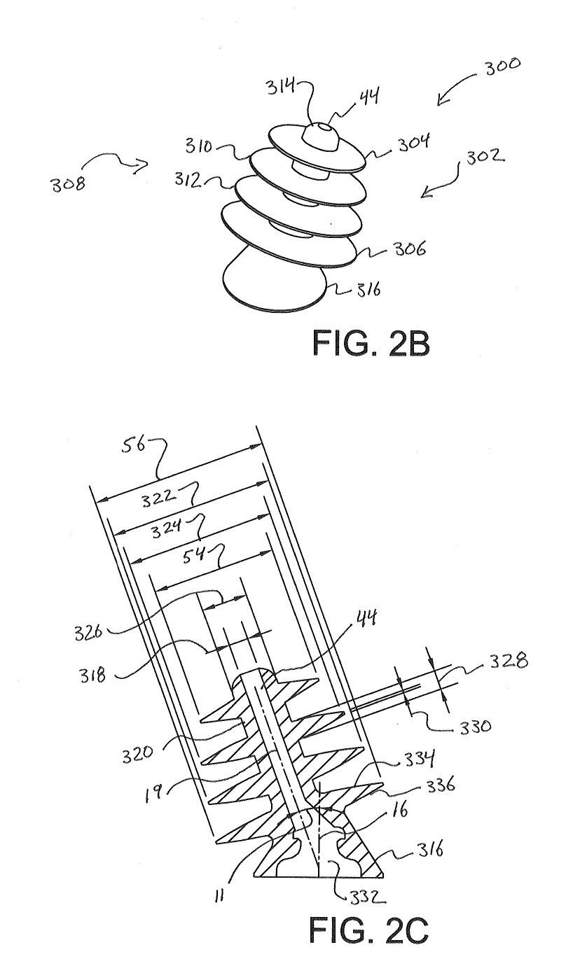

In the present embodiment (FIG. 1 and FIG. 2) the ear tip central axis 19 is composed of two main axes. The first axis being the ear tip base axis 16 which in this embodiment is centrally aligned within the ear tip base 12 and when the ear tip 10 is attached to a sound tube or sound device, the ear tip base 16 is aligned with a sound tube central axis 17. At the junction between the ear tip shaft 14 and ear tip base 12, the ear tip shaft axis 18 in this embodiment emanates radially away from the ear tip base central axis at an angular distance 11 which results in the angular asymmetrical arrangement of the present embodiment. The angular distance ranges from between 15° to approximately 30° depending upon the embodiment. In the present embodiment, angular distance is approximately 22°.

The ear tip base 12 in this particular embodiment has a base housing arrangement which is conical. Additional embodiments may include a cylindrical arrangement or other semi-cylindrical or semi-conical arrangements depending upon the design requirements. Furthermore, the ear tip shaft 14 in this particular embodiment is arranged in a semi-conical shape. The base of the ear tip shaft 14 provides for a wider diameter, and the top portion 28 of the ear tip shaft provides for a narrow diameter. The low profile ear tip flanges 20 include a base flange 22, a top flange 26, and an intermediate flange 24. While three low profile flanges are shown, more than three may be provided. At the minimum, a base flange 22 and a top flange 26 may be provided. Each of the low-profile flanges 20 are arranged radially about the ear tip shaft 14 in perpendicular alignment to the ear tip shaft axis 18.

Referring to FIG. 2, each of the low profile flanges has a flat roof 32 which extends perpendicularly away from the ear tip shaft axis 18, and in this particular embodiment the flat roof 32 is a circular roof which has an outer diameter edge. The outer diameter edge transitions from the flat roof to a downwardly transitioning radial wall 34. This downwardly transitioning radial wall stops at a radial wall bottom edge 50. Thus the ear tip flanges each form to face downward towards the base of the ear tip. Each ear tip flange has a flange height 40 which is defined by the flat rooftop edge 48 and the radial wall bottom edge 50. Between the radial wall bottom edge 50 and the flat rooftop edge 48 of the adjacent low-profile flange is a flange gap 42. The flange height 40 ranges from between approximately 1/16″ to approximately about ⅛″. The flange gap ranges from approximately 1/16″ to approximately 3/16″ with the present embodiment at approximately ⅛″.

To provide for proper seating on the sound device, the ear tip base 12 has a sound device concave seat 47. This is to match the outer convex shape of the sound device. Furthermore, a sound tube connection section 46 is provided which includes a semi-cylindrical inner seat where a male sound tube can be fitted into the sound tube connection section. The sound tube of the sound device is inserted into the sound channel 44 of the ear tip 10 and the sound device can emanate through the sound tube, then through the sound channel 44, and finally into the user's ear canal.

In the present embodiment, the low-profile ear tip flanges 20 range from a larger diameter 56 affiliated with the bottom flange 22, to a smaller diameter 54 affiliated with the top flange 26. The intermediate flange diameter 58 is affiliated with the intermediate flange 24. The ear tip shaft diameter 52 ranges from approximately 1/32″ to approximately ⅛″ at the present embodiment at approximately 1/16″. The bottom flange diameter 56 ranges from approximately ½″ to approximately 13/32″ depending upon the size of the ear tip. The intermediate flange diameter 58 ranges from approximately 15/32″ to approximately 11/32″. The top flange diameter 54 ranges from approximately 7/16″ to approximately 21/64″. The base diameter 51 of the ear tip base 12 in the present embodiment is approximately ⅜″.

Referring to FIG. 2A, a second embodiment of the asymmetrically aligned ear tip 10 is provided where the ear tip 10 has a curvilinearly aligned ear tip arrangement. Here the ear tip is asymmetrically aligned along a curvilinear ear tip axis 100. This provides the asymmetrically desired arrangement for fitting to the user's ear canal. Each of the low-profile flanges is circumferentially spaced along the curvilinear ear tip axis 100. The low-profile circumferentially aligned ear tip flanges 106A through 106C, are aligned perpendicular to the curvilinear arc.

In a third alternative embodiment and referring to FIG. 2B and FIG. 2C, an asymmetrically aligned ear tip 300 with low profile tapered disc ear tip flanges 302 is provided. Here the low profile tapered disc ear tip flanges 302 include four flanges. The four flanges include a top flange 304, a bottom flange 306, and a group of intermediate flanges 308 including a first intermediate flange 310 and a second intermediate flange 312 forming a total of four flanges equally spaced along the cylindrical ear tip shaft 320.

Each of the flanges has a flange top wall 334 and a flange bottom wall 336. Each of the top and bottom walls are equiangular in angular distance and in most cases are equilateral. The flanges are tapered from a wide flange base width 328 to a narrow flange tip width 330 forming in cross-section a conical flange shape projection.

As provided in the first embodiment, the low-profile tapered disc ear tip flanges 302 range from the greatest diameter at the base to the smallest diameter at the tip. For example, the bottom flange 306 has a bottom flange diameter 56 which is the greatest of the flanges, the next greatest being the second intermediate flange diameter 322, the next greatest being the first intermediate flange diameter 324 with the smallest flange size being the top flange diameter 54.

The cylindrical ear tip shaft 320 has a constant outer diameter 326 which forms the outer wall of the sound channel 44, the sound channel having a sound channel width 318. As previously mentioned in the first embodiment, the sound channel 44 intersects with the sound tube connection section 332 at an angular distance 11. The ear tip sound tube connection section 332 is configured to attach to a sound tube (not shown.)

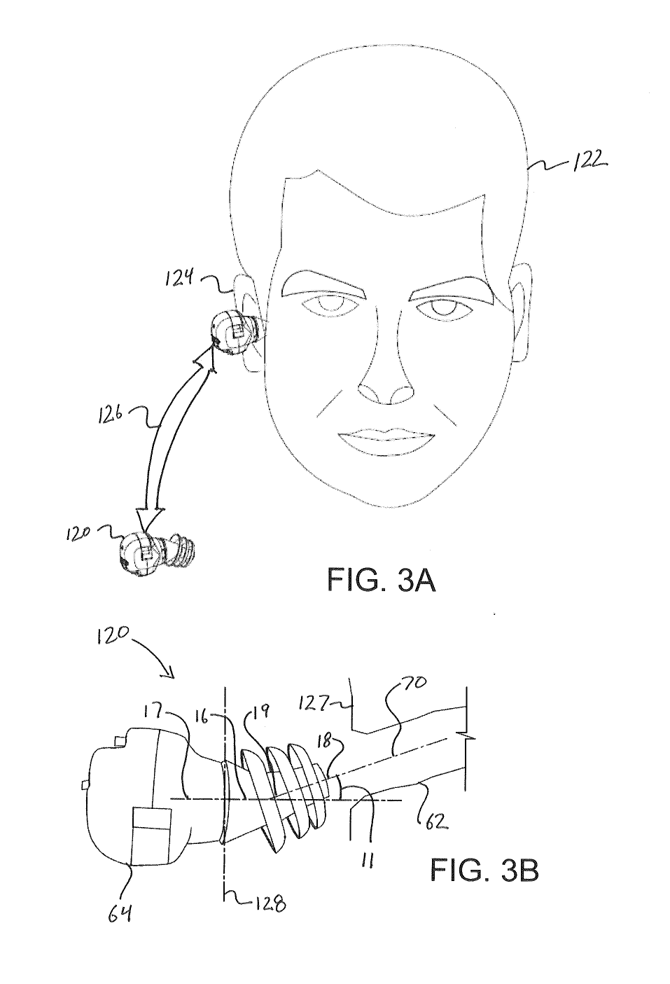

Referring to FIG. 3A, a user 122 can insert for example a combination sound amplifier with an asymmetrically aligned ear tip 120 into the user's ear 124 through utilization of the ear tip 126. Referring to FIG. 3B, while in this particular embodiment, the ear tip 10 is attached already to the sound device 64 which in this particular embodiment is a sound amplifier, the user can attach the sound device to the ear tip after the user has already installed the ear tip into the ear canal 62 of the user. Here the user will align the ear tip shaft axis 18 generally with the centerline of the ear canal axis 70. The junction between the base of the ear tip 12 and the sound device 64 forms a sound amplification seat plane 128 which is generally in parallel alignment with the outer ear wall 127 of the user's ear. This sound amplification seat plane 128 enables the sound device 64 to present the sound tube axis 17 generally perpendicular to the sound device seat plane 128. Furthermore, the angular distance 11 of the asymmetrically aligned ear tip 10 will provide for aligned insertion of the ear tip into the ear canal along the ear canal axis.

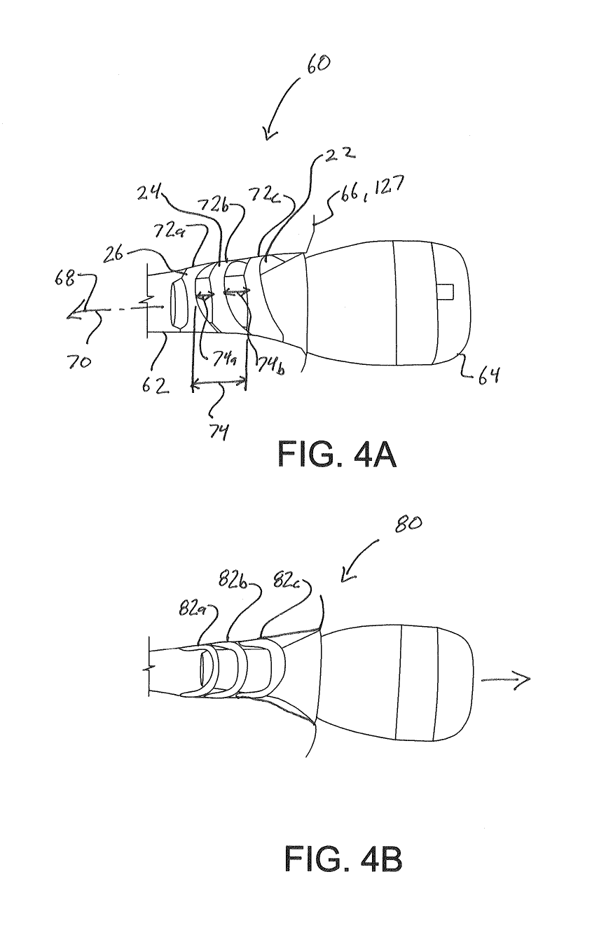

Referring to FIG. 4A, a discussion of the ear tip as inserted into the ear canal 62 will now be provided. The ear tip insertion configuration 60 generally provides for a downward deflection of the low-profile ear tip flanges 20 including the base flange 22, the intermediate flange 24, and a top flange 26.

Briefly, the ear tip 10 may be constructed of a silicon material, a rubber material, or a combination of materials which provide for a high level of elasticity enabling the low-profile ear tip flanges to easily flex in a downward deflection state as seen in FIG. 4A, or in an upward deflection state as seen in FIG. 4B.

During the downward deflection state when the ear tip 10 is inserted into the ear canal 62, the ear tip will form a sound deadening space which includes a sound deadening space 70 between the top flange 26 and the intermediate flange 24 as well as the flange seal 72A and 72B which is created when the ear tip flanges deform downward while pressing laterally against the ear wall to conform to the ear canal wall. Similarly, another sound deadening space is formed between the intermediate flange 24 and base flange 22 as well as the flange seals 72B and 72C. By providing the sound deadening space 74, the only sound entering the ear canal is generally limited to the sound through the ear tip sound channel 44 (FIG. 2). Furthermore to reduce any resonant feedback formed after the sound amplifier or sound device is turned on, the resonant feedback sound waves are reduced when having to travel through the sound deadening space 74.

During removal of the ear tip, as seen in FIG. 4B, the ear tip low-profile flanges can easily be configured into an upward deflection configuration 82A through 82C. This facilitates easy removal of the ear tip and ease of cleaning.

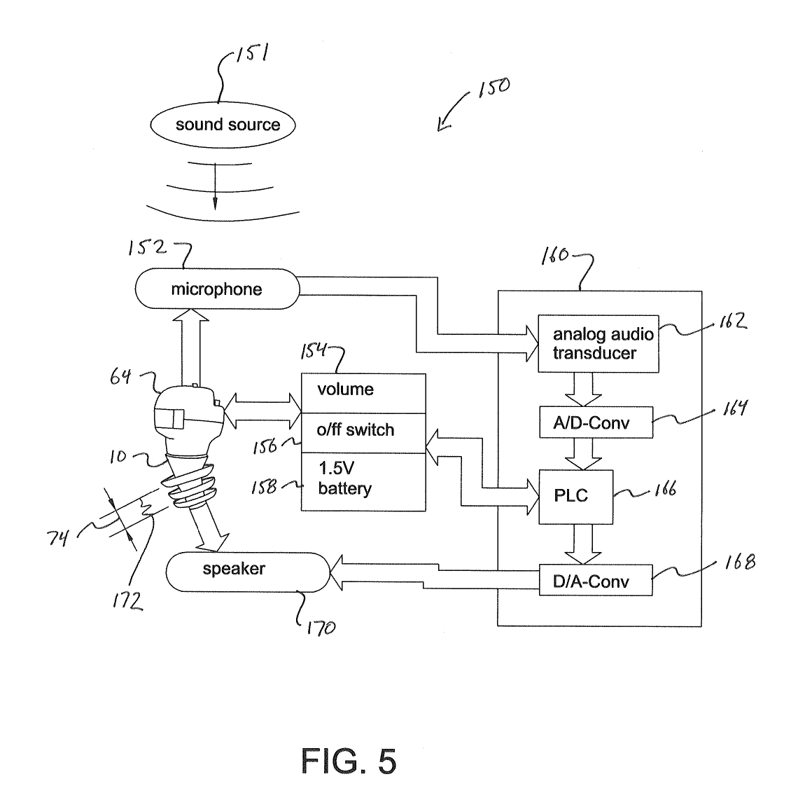

Referring to FIG. 5, a discussion of the ear tip in combination with a sound amplifier will now be provided. A sound amplifier resonance reduction system 150 is provided where the sound amplifier 64 is configured with a volume adjustment 154, a microphone 152, an on/off switch 156, and a 1.5 V battery 158. The sound amplifier 64 includes an amplifier circuit 160. The sound source 151 will emanate sound waves which the microphone 152 will pick up. The microphone 152 will transmit the analog sound signal to the analog audio transducer 162 resident within the amplifier circuit 160. The amplifier circuit 160 will then convert the analog signal to a digital signal through an analog to digital converter 164. The sound signal in its digital form is now processed through a programmable logic controller 166 which amplifies the sound signal. The programmable logic controller then sends the sound signal to the digital to analog converter 168. The amplified analog sound signal is sent to the speaker 170. The amplified sound emanating from the speaker passes through the sound channel 44 (FIG. 1) of the asymmetrically aligned ear tip 10 and into the user's ear canal. The sound deadening space 74 reduces resonant feedback 172 which is generated when the amplified sound interacts with the user's ear.

While the present embodiment utilizes a sound amplifier, the sound device can also include an earphone such as the iPod earbuds. The sound device can also be a Bluetooth wireless headset which would be utilized for cellular phones or wireless headset dictation, and the sound device can also be a hearing aid device.

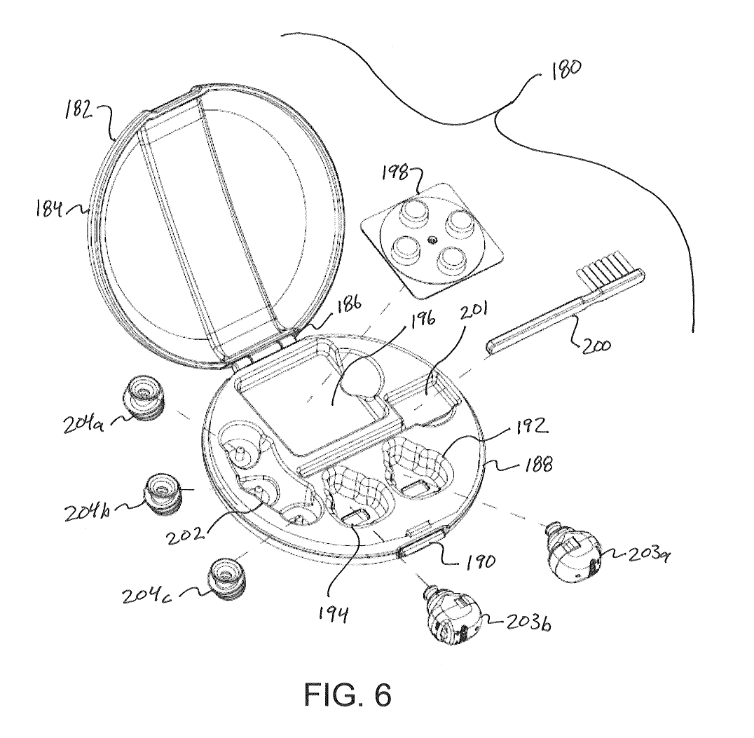

Referring to FIG. 6, a sound amplification with ear tip kit 180 is provided. A casing container 182 is provided in this particular embodiment in a somewhat clamshell shape where a lid 184 is attached to a hinge 186. A base 188 includes a plurality of component seats. These component seats include a first sound amplification seat 192, a second sound amplification seat 194, a brush seat 201, a battery seat 196, and an ear tip seat 202. At least three asymmetrically aligned ear tips 204A though 204C can be seated within the ear tip seats 202. At least two sound amplifiers 203A and 203B can be seated in the sound amplification seats. In this particular embodiment, a pack of four 1.5 V batteries 198 can be seated in the battery seat 196 and a brush 200 which is utilized for cleaning can be seated in the brush seat.

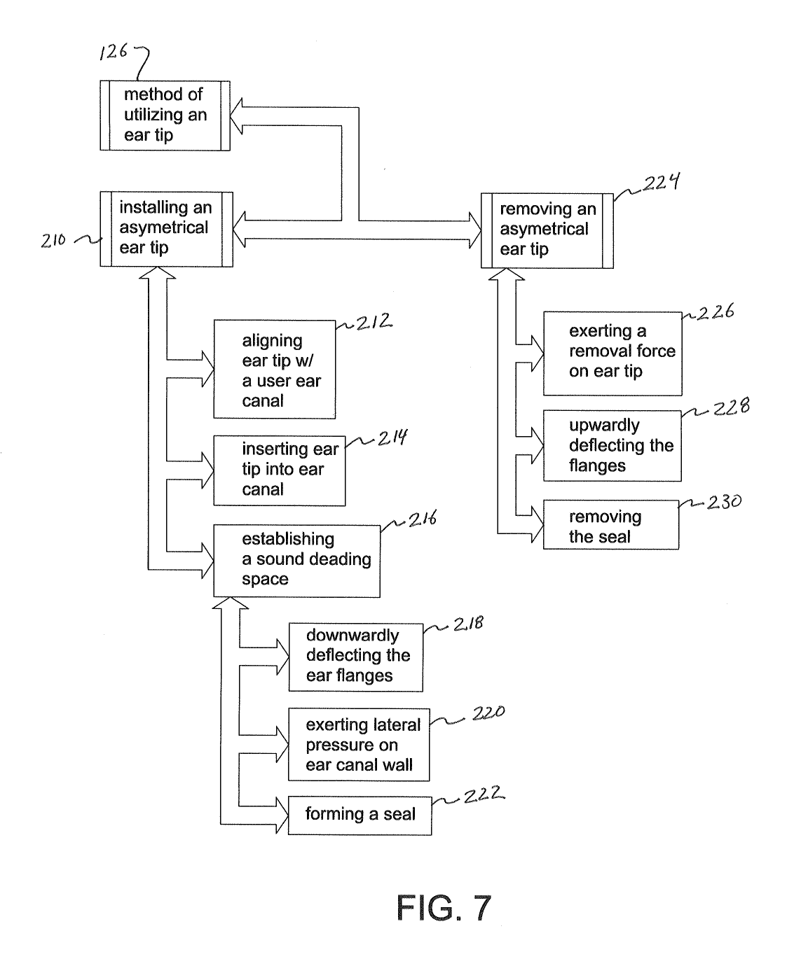

A brief discussion of the method of utilizing an ear tip 126 will now be provided. Reference will be made to FIG. 7 as well as FIGS. 4A and 4B. A user can install an asymmetrical ear tip 210 by first aligning the ear tip with the user's ear canal at step 212. After aligning the ear tip, the user can insert the ear tip into the ear canal at step 214. In doing so, the user can establish a sound deadening space at step 216. In order to establish the sound deadening space at step 216, the user will downwardly deflect the ear flanges at step 218. By doing so, the user will exert lateral pressure on the ear canal wall at step 220 which will form a seal at step 222. After use, the user can then remove the asymmetrical ear tip at step 224 by: exerting a removal force on the ear tip at step 226 by for example pulling the ear tip laterally away from the user's ear. By doing so, the user will upwardly deflect the low-profile ear tip flanges at step 228. And in doing so, the user will remove the seal at step 230.

Therefore I claim:

1. An ear tip for a sound device, said ear tip comprising:
a. an asymmetrical arrangement comprising: an ear tip base, an ear tip shaft, a first group of low profile flanges, all arranged along an ear tip central axis;
b. said ear tip base comprising a base housing arrangement arranged about said ear tip central axis comprising an ear tip base axis, an ear tip shaft axis;
c. said ear tip base further comprising a sound tube connection section, a sound channel extending through said ear tip base and said ear tip shaft along said ear tip central axis to transmit sound emanating from a sound tube through said ear tip into a user's ear canal comprising an ear wall;
d. said ear tip shaft arranged about said ear tip shaft axis, said ear tip shaft axis emanating away from said ear tip base central axis further providing said asymmetrical arrangement of said ear tip;
e. said first group of low profile flanges arranged radially about said ear tip shaft in perpendicular alignment to said ear tip shaft axis; said first group of low profile flanges comprising a first flange, a second flange, a group of intermediate flanges disposed between said first flange and said second flange, said group of intermediate flanges comprising: a first intermediate flange;
f. said first group of low profile flanges further comprising a spacing arrangement wherein each of said low profile flanges are arranged along said ear tip shaft axis to provide a flange gap between each of said first group of low profile flanges;
g. whereby utilization of said ear tip asymmetrical arrangement generally matches said users ear canal alignment allowing said low profile flanges to seal against said ear wall to attenuate sound and reduce sound resonance.

2. The ear tip according to claim 1 wherein said group of intermediate flanges further comprises: a second intermediate flange.

3. The ear tip according to claim 1 wherein said first group of low-profile flanges each comprise: a flat roof, a downwardly transitioning radial wall, a flange height defined by a top edge of said flat roof and a bottom edge of said radial wall, a flange diameter.

4. The ear tip according to the claim 1 wherein said first group of low-profile flanges each comprise: a tapered disc arrangement comprising a flange top wall and a flange bottom wall equilaterally arranged to form in cross-section a conical flange.

5. The ear tip according to claim 1 wherein said ear tip shaft further comprises:
an ear tip shaft arrangement about said ear tip shaft axis, said ear tip shaft axis emanating radially away from said ear tip base central axis at an angular distance resulting in an angularly asymmetrical arrangement of said ear tip.

6. The ear tip according to claim 5 wherein said angular distance further comprises an angular range of between 15° and 30°.

7. The ear tip according to claim 1 wherein said ear tip further comprises: said ear tip axis further comprising: a curvilinear arc axis.

8. The ear tip according to claim 1 wherein said ear tip base further comprises a cylindrical shaft arranged about said curvilinear arc axis.

9. The ear tip according to claim 8 wherein said ear tip shaft further comprises: a cylindrical shaft arrangement matching a diameter of said cylindrical ear tip base shaft, said ear tip shaft axis aligned with a curvilinear arc axis resulting in a curvilinear asymmetrical arrangement of said ear tip.

10. The ear tip according to claim 9 wherein said group of low profile flanges further comprises: a circumferentially aligned spacing wherein said group of low profile flanges is aligned perpendicular to said curvilinear arc.

11. The ear tip according to claim 1 wherein said first group of low profile flanges range in diameter from a large diameter to a small diameter, said first flange comprising said large diameter, said second flange comprising said small diameter, said group of intermediate flanges comprising intermediate diameters less than said large diameter but greater than said small diameter.

12. The ear tip according to claim 1 wherein said flange gap further comprises: a distance between said radial wall bottom edge and said flat roof top edge of an adjacent low-profile flange.

13. The ear tip according to claim 1 wherein said first group of low profile flanges further comprises: a downward deflection configuration for creation of a flange seal during insertion of said ear tip into said ear canal.

14. The ear tip according to claim 13 wherein said first group of low profile flanges further comprises: formation of a sound deadening space formed between said low profile flanges and said flange seal.

15. The ear tip according to claim 1 wherein said first group of low profile flanges further comprises: an upward deflection configuration during a removal of said ear tip from said ear canal.

16. The ear tip according to claim 1 wherein said first group of low profile flanges further comprises: a flexible material providing a high elasticity for temporary de-formation during a deformed state and re-formation during an un-deformed state.

17. The ear tip according to claim 1 wherein said ear tip base housing arrangement further comprises: a conical arrangement.

18. The ear tip according to claim 1 wherein said ear tip base housing arrangement further comprises: a cylindrical arrangement.

19. The ear tip according to claim 1 wherein said ear tip shaft further comprises: a conical arrangement.

20. The ear tip according to claim 1 wherein said ear tip shaft further comprises: a cylindrical arrangement.

21. The ear tip according to claim 1 wherein said ear tip further comprises: an ear tip material primarily consisting of silicone.

22. The ear tip according to claim 1 wherein said ear tip further comprises: an ear tip material primarily consisting of rubber.

23. The ear tip according to claim 1 wherein said ear tip base further comprises: a sound device concave seat.

24. The ear tip according to claim 1 wherein said ear tip further comprises: said sound tube fixedly attached to a sound amplification device configured to amplify a sound and transmit an amplified sound through said sound tube and said sound channel of said ear tip into said ear canal.

25. The ear tip according to claim 1 wherein said ear tip further comprises: said sound tube fixedly attached to an ear phone, wherein said ear phone produces a sound for transmission through said sound tube and said sound channel of said ear tip into said ear canal.

26. The ear tip according to claim 1 wherein said ear tip further comprises: said sound tube fixedly attached to a wireless headset, said wireless headset receiving a Bluetooth signal from a cell phone, transforming said signal, and producing a sound for transmission through said sound tube and said sound channel of said ear tip into said ear canal.

27. An ear tip utilization method comprising:
a. installing an asymmetrical ear tip onto a sound device by aligning a sound tube connection section within said ear tip with a sound tube fixedly attached to said sound device;
b. aligning said asymmetrical ear tip with a user's ear canal, said asymmetrical ear tip comprising an ear tip base, an ear tip shaft, a first group of low-profile flanges, all arranged along an ear tip central axis;
c. said ear tip central axis comprising an ear tip base axis, an ear tip shaft axis, said ear tip shaft axis emanating away from said ear tip base axis providing an asymmetrical arrangement of said ear tip;
d. said user ear canal comprising an ear canal central axis and an ear canal wall;
e. inserting said the asymmetrical ear tip into said ear canal by aligning said ear tip central axis with said ear canal's central axis.

28. The method according to claim 27 wherein said method further comprises:
a. establishing a sound deadening space within said ear canal by:
i. deflecting downward said first group of low-profile flanges;
ii. exerting lateral pressure from said first group of low-profile flanges onto said ear canal wall;
iii. forming a seal between said first group of low-profile flanges and said ear canal wall.

29. The method according to claim 28 wherein said method further comprises:
a. removing said the asymmetrical ear tip by:
i. exerting a removal force on said ear tip;
ii. upwardly deflecting said first group of low-profile flanges;
iii. removing said seal between said first group of low-profile flanges and said ear canal wall.

30. The method according to claim 28 wherein said method further comprises:
a. said sound device comprising a sound amplifier;
b. receiving a sound from a sound source in a microphone arranged within said sound amplifier;
c. transforming said sound into an analog sound signal within said sound amplifier;
d. converting said analog sound signal into a digital sound signal within said sound amplifier by utilizing an analog to digital converter:
e. amplifying said digital sound signal within said sound amplifier utilizing a programmable logic controller;
f. converting said amplified digital sound signal into an amplified analog sound signal through a digital to analog converter within said sound amplifier;
g. producing an amplified sound through a sound speaker within said sound amplifier;
h. transmitting said amplified sound through said sound tube of said sound amplifier;
i. transmitting said amplified sound through said sound channel of said asymmetrically aligned ear tip;
j. receiving said amplified sound in said user's ear canal;
k. reducing sound feedback generated within said user's ear canal by:
i. utilizing said sound deadening space to reduce resonant sound feedback.

31. A sound amplification ear tip kit comprising:
a. at least one asymmetrical ear tip comprising: an ear tip base, an ear tip shaft, a first group of low-profile flanges, all arranged along an ear tip central axis;
b. said ear tip central axis comprising an ear tip base axis, an ear tip shaft axis; said ear tip shaft axis emanating away from said ear tip base axis providing an asymmetrical arrangement of said asymmetrical ear tip;
c. said asymmetrical ear tip further comprising a sound channel extending through said ear tip base and said ear tip shaft along said ear tip central axis;
d. a kit casing comprising a casing lid, a casing hinge, and a casing base; said casing base comprising seating for receiving at least one asymmetrical ear tip; at least one sound amplifier; at least one brush; at least one battery pack.
